(19) United States
(12) Patent Application Publication
(10) Pub. No.: US 2015/0048515 A1
(43) Pub. Date: Feb. 19, 2015

(54) FABRICATION OF A SUBSTRATE WITH AN EMBEDDED DIE USING PROJECTION PATTERNING AND ASSOCIATED PACKAGE CONFIGURATIONS

(71) Applicants: Chong Zhang, Chandler, AZ (US); Stefanie M. Lotz, Phoenix, AZ (US); Islam A. Salama, Chandler, AZ (US)

(72) Inventors: Chong Zhang, Chandler, AZ (US); Stefanie M. Lotz, Phoenix, AZ (US); Islam A. Salama, Chandler, AZ (US)

(21) Appl. No.: 13/968,271

(22) Filed: Aug. 15, 2013

(51) Int. Cl. H01L 21/768; H01L 23/538

(52) U.S. Cl. CPC H01L 21/76879; H01L 21/76802; H01L 23/5384
USPC 257/774; 438/675

(57) ABSTRACT

Embodiments of the present disclosure are directed towards techniques and configurations for using projection patterning in making an electronic substrate with an embedded die. In one embodiment, a method may include providing a die embedded in dielectric material of a substrate, and projecting a laser beam through a mask with a preconfigured pattern to create a projected mask pattern on a surface of the dielectric material in accordance with the preconfigured pattern. The projected mask pattern may include a via disposed over the die. Other embodiments may be described and/or claimed.

### FIELD

Embodiments of the present disclosure generally relate to the field of integrated circuits, and more particularly, to techniques and configurations for making a substrate with an embedded die using projection patterning, in integrated circuit assemblies.

### BACKGROUND

To overcome bandwidth limitations between logic-to-logic and/or logic-to-memory communications in multichip packages (MCPs), embedded bridge dies, such as silicon bridges (SiB), have been proposed as an instrument to achieve such high density die-to-die interconnection. The package connection from logic or memory dies to the package may utilize a microvia-based interconnection to the embedded bridge die. A finer pitch of high bandwidth memory (HBM) dies and/or die stacks (e.g., the Joint Electron Devices Engineering Council (JEDEC) standard of 55 μm pitch) drives stringent high density interconnection (HDI) package substrate design rule requirements for minimum controlled-collapse chip-connection (C4) interconnect pitch of CPU-to-memory die connection.

Currently, laser drilling may be used to make microvia-based interconnection. For example, laser drilling may utilize Galvano mirrors to position a CO₂ laser beam to a desired location to perform the microvia drilling. However, providing a finer pitch for future computing devices may be challenging using present technologies. For example, current laser drilling techniques may still not be able to achieve a via pitch of 55 μm or less.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) assembly with an electronic substrate with an embedded die, in accordance with some embodiments.

FIG. 2 schematically illustrates an example machine configuration of a laser projection patterning system for making an electronic substrate with an embedded die, in accordance with some embodiments.

FIG. 3 schematically illustrates multiple section views with imaginary cutting planes parallel to a plane of the pattern mask in FIG. 2, in accordance with some embodiments.

FIG. 4 schematically illustrates a flow diagram of a package substrate fabrication process of using projection patterning in making electronic substrate with an embedded die, in accordance with some embodiments.

FIG. 5 schematically illustrates cross-sectional views of some selected operations in connection with the package substrate fabrication process illustrated in FIG. 4, in accordance with some embodiments.

FIG. 6 schematically illustrates cross-sectional views of some other selected operations, in continuation to FIG. 5, in connection with the package substrate fabrication process illustrated in FIG. 4, in accordance with some embodiments.

FIG. 7 schematically illustrates cross-sectional views of yet some selected operations in connection with the package substrate fabrication process illustrated in FIG. 4, in accordance with some embodiments.

FIG. 8 schematically illustrates cross-sectional views of some other selected operations, in continuation to FIG. 7, in connection with the package substrate fabrication process illustrated in FIG. 4, in accordance with some embodiments.

FIG. 9 schematically illustrates cross-sectional views of some selected microvias made using projection patterning, in accordance with some embodiments.

FIG. 10 schematically illustrates a computing device including an electronic substrate with embedded die as described herein, in accordance with some embodiments.

### DETAILED DESCRIPTION

Embodiments of the present disclosure describe techniques and configurations for using projection patterning in making an electronic substrate with an embedded die in integrated circuit assemblies. For example, techniques described herein may be used to fabricate an electronic substrate including high density interconnect (HDI) routing to provide higher bandwidth for communication between dies mounted on the substrate using the embedded die (e.g., bridge). In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “in embodiments,” or “in some embodiments” which may each refer to one or more of the same or different embodiments. Furthermore, the terms “comprising,” “including,” “having,” and the like, as used with respect to embodiments of the present disclosure, are synonymous.

The term “coupled with” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

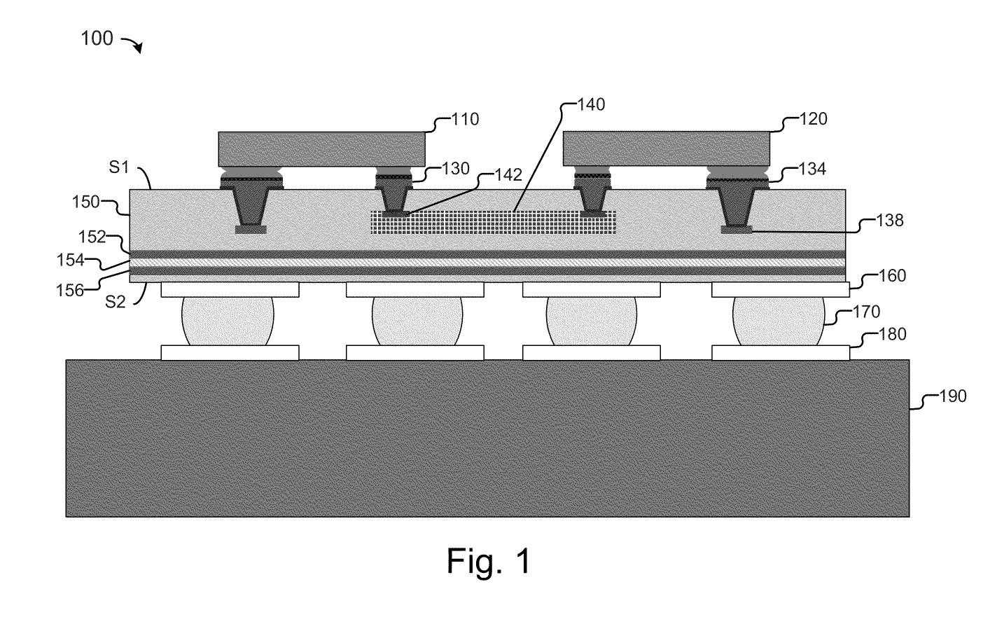

FIG. 1 schematically illustrates a cross-section side view of an example IC assembly 100 with an electronic substrate (e.g., package substrate 150) with an embedded die partially made using projection patterning, in accordance with some embodiments. As used herein, first level interconnect (FLI) may refer to the interconnect between a die (e.g., die 110 or 120) and a package substrate (e.g., package substrate 150) while second level interconnect (SLI) may refer to the interconnect between the package substrate (e.g., package substrate 150) and a circuit board (e.g., circuit board 190). In embodiments, IC assembly 100 may include one or more dies, such as die 110 and die 120, electrically and/or physically coupled with package substrate 150 via one or more FLI structures. Package substrate 150 may further be electrically coupled with circuit board 190 via one or more SLI structures.

Die 110 or 120 may represent a discrete unit made from a semiconductor material using semiconductor fabrication techniques such as thin film deposition, lithography, etching and the like. In some embodiments, die 110 or 120 may include, or be a part of a processor, memory, ASIC, or SoC. Dies 110 and 120 can be attached to package substrate 150 according to a variety of suitable configurations including, a flip-chip configuration, as depicted, or other configurations such as, for example, being embedded in package substrate 150. In the flip-chip configuration, die 110 or 120 may be attached to a surface (e.g., side S1) of package substrate 150 using FLI structures such as interconnect structures 130, 134, which are configured to electrically and/or mechanically couple the dies 110, 120 with the package substrate 150 and route electrical signals between one or more of the dies 110, 120 and other electrical components. In some embodiments, the electrical signals may include input/output (I/O) signals and/or power/ground associated with operation of the dies 110 and/or 120.

The interconnect structure 130 may be electrically coupled with the bridge 140 to route electrical signals between the dies 110, 120 using the bridge 140. The interconnect structure 134 may be configured to route electrical signals between a die (e.g., die 120) and a routing feature 138 belonging to an electrical pathway which may pass through the package substrate 150 from a first side S1 to a second side S2 that is opposite to the first side S1. As an example, the electrical pathway may include other interconnect structures, such as, for example, trenches, vias, traces, or conductive layers (e.g., conductive layer 152 and 156 on the two sides of dielectric layer 154) and the like that are configured to route electrical signals of the die 110 or 120 between the first side S1 and the second side S2 of the package substrate 150.

The interconnect structure 130 or 134, the routing feature 138, and conductive layer 152 or 156 are merely example structures for the sake of discussion. Electrical pathways may include any of a variety of suitable interconnect structures and/or layers to couple dies 110 and 120 or other dies (not shown) with the package substrate 150. The package substrate 150 may include more or fewer interconnect structures or layers than depicted. In some embodiments, an electrically insulative material such as, for example, molding compound or underfill material (not shown) may partially encapsulate a portion of die 110 or 120, and/or interconnect structures 130 and 134.

In some embodiments, bridge 140 may be configured to electrically connect dies 110 and 120 with one another. In some embodiments, bridge 140 may include interconnect structures (e.g., die contacts 142) to serve as electrical routing features between the dies 110 and 120. In some embodiments, bridge 140 may be connected with routing structures (e.g., interconnect structures 130) that provides routes for electrical signals. As an example, interconnect structures 130 above bridge 140 (e.g., for routing electrical signals of dies 110 and 120 through bridge 140) may have a via pitch of 55 micrometer (μm) or less. In some embodiments, a bridge may be disposed between some dies on package substrate 150 and not between other dies. In some embodiments, a bridge may not be visible from a top view. As an example, bridge 140 may be embedded in a cavity of package substrate 150 in some embodiments.

Bridge 140 may include a bridge substrate composed of glass or a semiconductor material, such as silicon (Si) having electrical routing interconnect features formed thereon, to provide a chip-to-chip connection between the dies 110 and 120. Bridge 140 may be composed of other suitable materials in other embodiments. In some embodiments, the package substrate 150 may include multiple embedded bridges to route electrical signals between multiple dies.

In some embodiments, package substrate 150 is an epoxy-based laminate substrate having a core and/or build-up layers such as, for example, an Ajinomoto Build-up Film (ABF) substrate. Package substrate 150 may include other suitable types of substrates in other embodiments including, for example, substrates formed from glass, ceramic, or semiconductor materials.

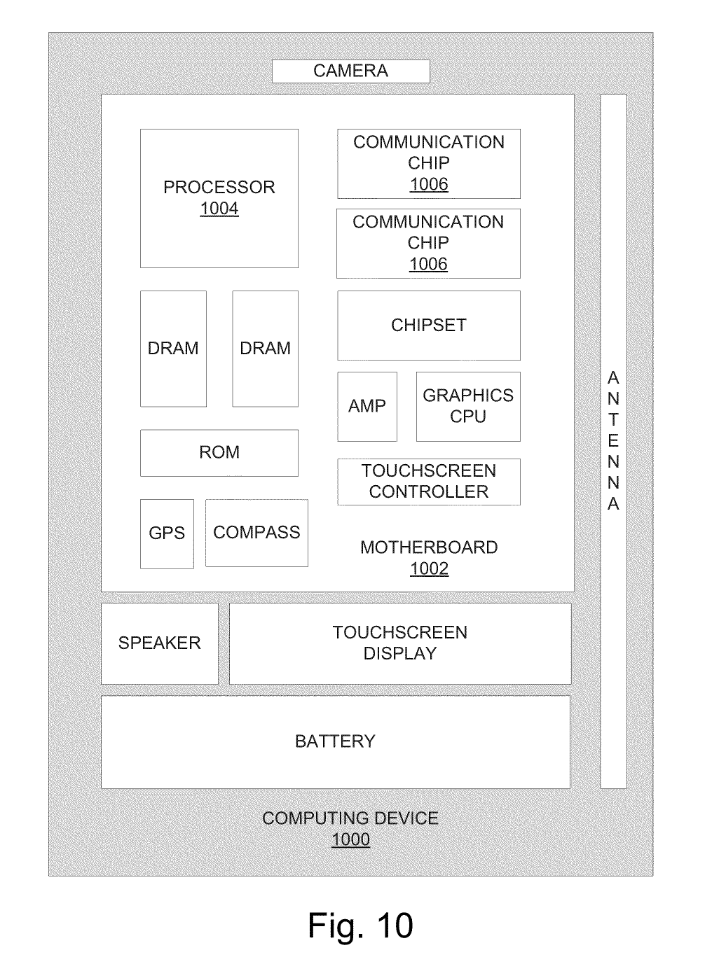

Circuit board 190 may be a printed circuit board (PCB) composed of an electrically insulative material such as an epoxy laminate. For example, circuit board 190 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Structures such as traces, trenches, vias may be formed through the electrically insulating layers to route the electrical signals of the die 110 or 120 through circuit board 190. Circuit board 190 may be composed of other suitable materials in other embodiments. In some embodiments, circuit board 190 is a motherboard (e.g., motherboard 1002 of FIG. 10).

Package-level interconnects such as, for example, solder balls 170, which may be configured in a ball-grid array (BGA) configuration, or land-grid array (LGA) structures may be coupled to one or more lands (hereinafter “lands 160”) on package substrate 150 and one or more pads 180 on circuit board 190 to form corresponding electrical connection that are configured to further route the electrical signals between the package substrate 150 and the circuit board 190. Lands 160 and/or pads 180 may be composed of any suitable electrically conductive material such as metal including, for example, nickel (Ni), palladium (Pd), gold (Au), silver (Ag), copper (Cu), and combinations thereof. Other suitable techniques to physically and/or electrically couple package substrate 150 with circuit board 190 may be used in other embodiments.

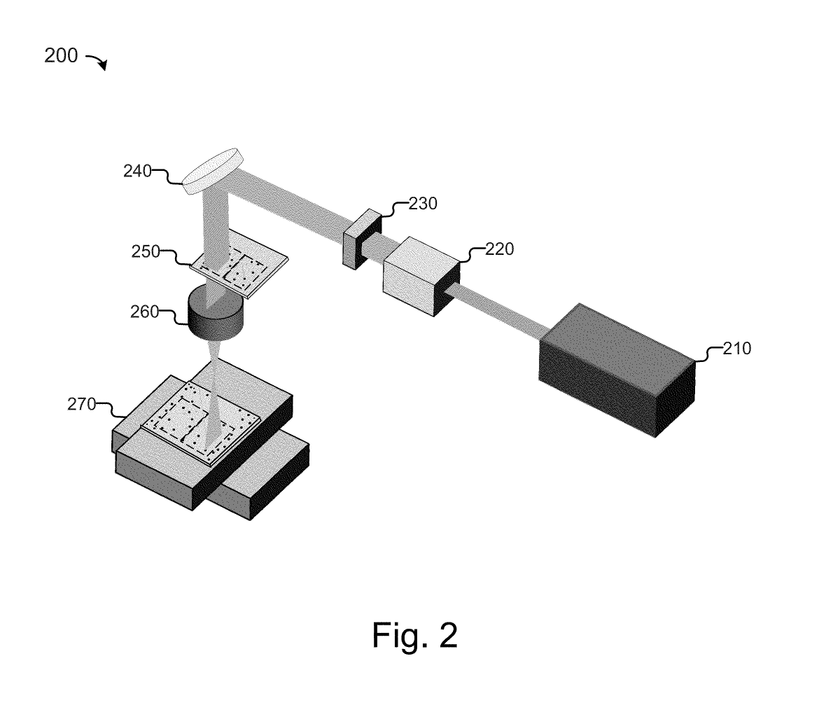

FIG. 2 schematically illustrates an example system or machine 200 for laser projection patterning for making an electronic substrate with an embedded die, in accordance with some embodiments. Machine 200 may include laser resonator 210, beam homogenizer 220, aperture 230, mirror 240, pattern mask 250, projection lens 260, and table 270, selectively coupled to each other.

In embodiments, the laser source may be excimer, solid state UV, CO₂ laser, or other types of laser. Excimer laser may have better resolution, more uniform profile, and higher power than solid state UV laser or CO₂ laser. In embodiments, laser resonator 210 may include mirrors and other optical components, and enable a laser radiation to circulate and pass a gain medium to increase power gains. In other words, laser resonator 210 may amplify the laser light, then a certain fraction of the laser energy may be used as the laser output to beam homogenizer 220. In embodiments, beam homogenizer 220 may be coupled with aperture 230 and mirror 240, and may be used to produce a highly uniform flat-top beam from the laser output.

In embodiments, pattern mask 250 may be placed in the light path of the flat-top beam. Pattern mask 250 may have a preconfigured pattern. Pattern mask 250 may be stationary in some embodiments and movable in other embodiments. In embodiments, projection lens 260 may be further placed under pattern mask 250 to project the laser beam through pattern mask 250 onto a dielectric surface of a substrate placed on table 270.

In embodiments, the substrate may have one or more embedded dies. The laser beam may be modified such that during projecting the laser beam, the laser beam may only cover a portion of pattern mask 250 that corresponds to an area on the dielectric surface over an embedded die. In embodiments, table 270 may be an X-Y table that may move the substrate with a coordinated opposing motion in connection with the movement of pattern mask 250, either in a constant speed or a variable speed. In embodiments, the laser beam may be projected through pattern mask 250 to drill a projected mask pattern through the dielectric material in accordance with the preconfigured pattern of pattern mask 250. Accordingly, the laser beam may cause one or more vias being created over the one or more dies embedded in the substrate. The machine 200 may include more or fewer components than depicted in some embodiments and may comport with other well-known principles of laser projection patterning in other embodiments.

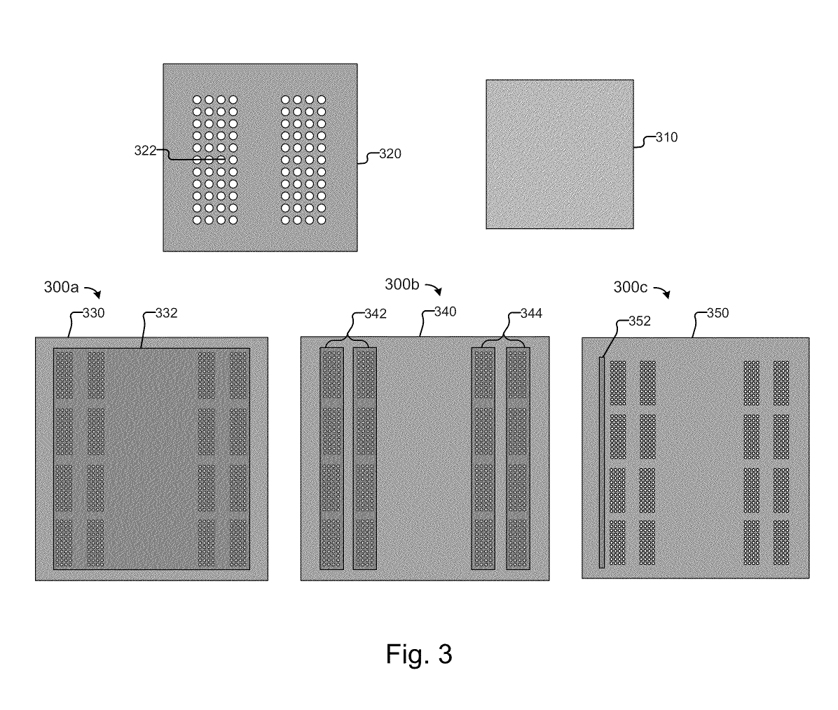

FIG. 3 schematically illustrates multiple section views with imaginary cutting planes parallel to a plane of the pattern mask 250 in FIG. 2, in accordance with some embodiments. In embodiments, beam 310 may be a highly uniform flat-top beam, and mask 320 may have a preconfigured pattern 322, as can be seen.

Stationary masks may be utilized to realize pattern projection on a substrate. In embodiments, a stationary mask may be used to project a pattern, e.g., pattern 322, on either one single die or a single unit featuring multiple dies, e.g., 8-10 dies. In some embodiments of single die projection, table 270 may be moved between each die projection to align the stationary mask with the target projection area over each die. In some embodiments of single unit projection, table 270 may be moved between each unit projection to align the stationary mask with the target projection area over each unit.

In some embodiments of single unit projection (e.g., at 300a), a large laser beam 332 may be used to cover almost the entire area of the unit beneath mask 330, which may feature multiple dies, e.g., 8 dies. In this case, the process throughput of pattern projection may be improved over the single die projection approach, partially because pattern projection may be realized over multiple dies simultaneously, and subsequently the reduced table movement necessary to cover all units on a substrate. However, the laser energy may be inefficiently utilized in this case, for example, due to the blockage of a large portion of the laser beam 332 by mask 330, e.g., at the center of mask 330, as can be seen. In some embodiments of single unit projection (e.g., at 300b), the laser energy may be more efficiently utilized by shaping or slitting laser beam 332 to laser beam 342 and 344 to cover only a portion of mask 340 corresponding to where the ultra-fine microvias are to be formed over the bridge die. In embodiments, the splitting of the laser beam may be realized by spatial beam splitter or temporal beam switcher.

Moving masks may also be utilized to realize pattern projection on a substrate. In embodiments (e.g., at 300c), mask 350 may have a preconfigured pattern or scheme for microvia drilling over one or more embedded bridges, e.g., bridge 140 in FIG. 1. Laser beam 352 may be shaped to cover only a partial area of mask 350. Mask 350 may be moved to transfer the preconfigured pattern or scheme onto the substrate. As an example, coordinated opposing motion imaging (COMI) technique may be used wherein the mask and the substrate may move oppositely for imaging purpose. As an example, mask 350 may move to left while the substrate may move to right. In some embodiments, the moving speed mask 350 and/or the substrate may be increased for inactive area, e.g., the middle area of the mask 350, in order to improve throughput.

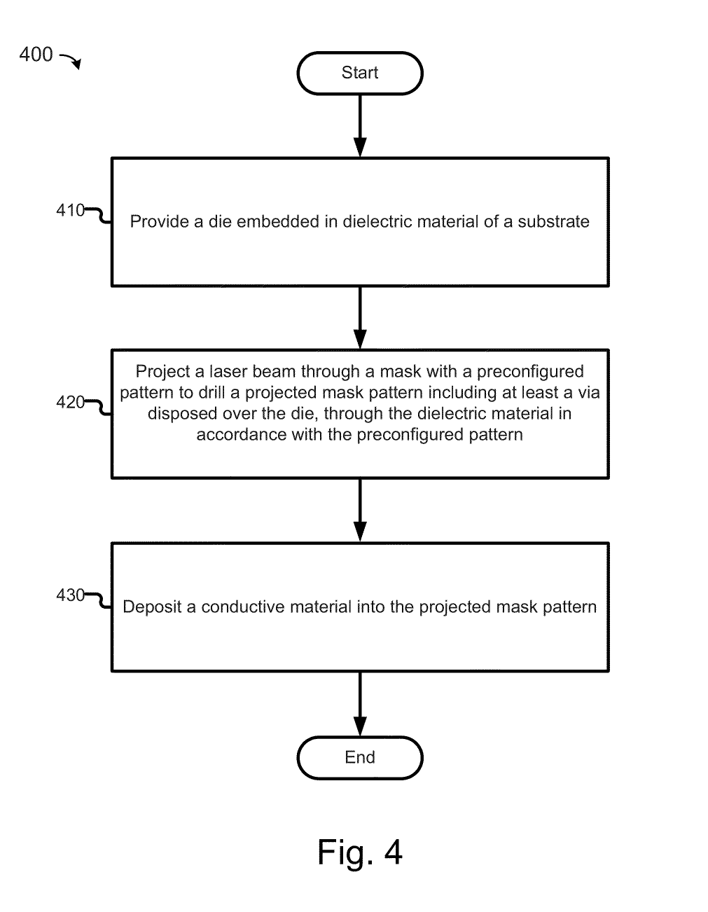

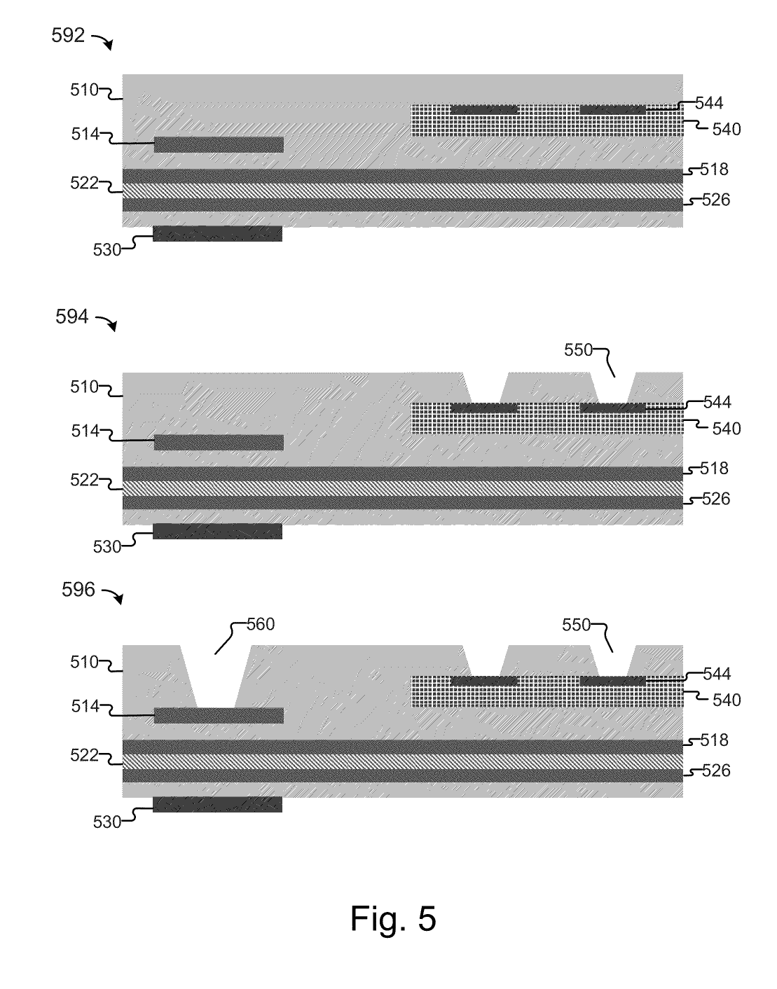

FIG. 4 schematically illustrates a flow diagram of a package substrate fabrication process 400 of using projection patterning in making an electronic substrate (e.g., package substrate 150 of FIG. 1) with an embedded die (e.g., bridge 140 of FIG. 1), in accordance with some embodiments. The process 400 may comport with embodiments described in connection with FIGS. 5-8 according to various embodiments.

At block 410, the process 400 may include providing a die (e.g., bridge 140 of FIG. 1) in dielectric material of a substrate. In embodiments, the die may be composed of glass or a semiconductor material (e.g., Si) and include electrical routing features to route electrical signals among other dies. In some embodiments, the die may be disposed in or within a plane formed by one or more build-up layers of the substrate. For example, as can be seen in the depicted embodiment in connection with FIG. 1, bridge 140 is embedded in the build-up layers of package substrate 150. In some embodiments, forming the die (e.g., bridge 140 of FIG. 1) disposed in a plane of the build-up layers may be realized by embedding the die in build-up layers as part of the formation of the build-up layers. In other embodiments, forming the die disposed in a plane of the build-up layers may be realized by forming a cavity in the build-up layers and placing the die in the cavity subsequent to formation of the build-up layers, according to any suitable technique.

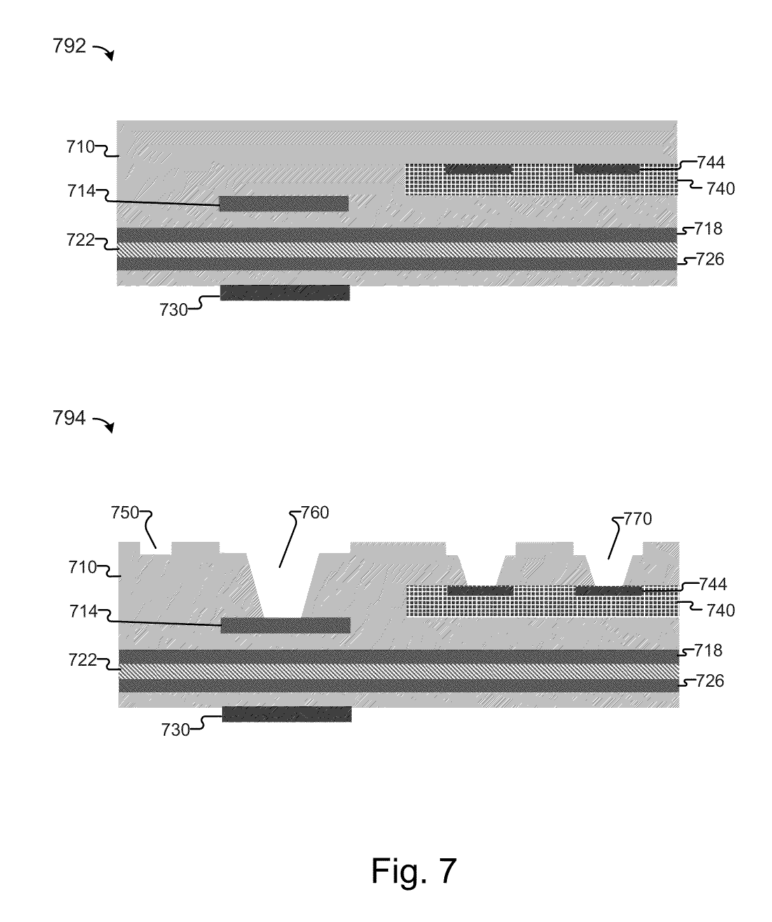

At block 420, the process 400 may include projecting a laser beam through a mask with a preconfigured pattern to drill a projected mask pattern, including at least a via disposed over the die, through the dielectric material in accordance with the preconfigured pattern. In embodiments, excimer may be used for via drilling over the embedded die, e.g., a Si bridge (SiB) die. Subsequently, carbon dioxide (CO₂) laser may be used for via drilling in a region of the dielectric material that is not over the die. In embodiments, excimer may be used to drill via, pad, trace, and/or other routing features concurrently. As an example, a grey scale mask may be used to realize different etching depth for via, pad, trace, and/or other routing features. Block 420 may be performed during fabrication described in connection with FIGS. 5 and 7 according to various embodiments.

At block 430, the process 400 may include depositing an electrically conductive material into the projected mask pattern. In embodiments, an interconnect structure (e.g., interconnect structure 130 of FIG. 1) may be partially formed with the electrically conductive material, and the interconnect structure may be connected with the embedded die to route electrical signals beyond a surface of the substrate. In embodiments, the interconnect structure may electrically couple the embedded die to other dies.

In one embodiment, the electrically conductive material may include copper (Cu). In some embodiments, the electrically conductive material may include, for example, aluminum (Al), silver (Ag), nickel (Ni), tantalum (Ta), hafnium (Hf), niobium (Nb), zirconium (Zr), vanadium (V), tungsten (W), or combinations thereof. In some embodiments, the electrically conductive material may include conductive ceramics, such as tantalum nitride, indium oxide, copper silicide, tungsten nitride, and titanium nitride. In other embodiments, the electrically conductive material may include other chemical compositions, or combinations thereof.

In embodiments, the projected mask pattern filled with the electrically conductive material may include structures such as, for example, traces, trenches, vias, lands, pads or other structures that provide corresponding electrical pathways for electrical signals through the package substrate. In embodiments, desmear and electroless Cu plating operations may be used before depositing the electrically conductive material into the projected mask pattern. In some embodiments, dry film resist (DFR) lamination, exposure and development operations may also be used before depositing the electrically conductive material into the projected mask pattern. In some embodiments, semi-additive process (SAP) plating operations may be used to deposit the electrically conductive material into the projected mask pattern, and DFR stripping and electroless removal operations may be used after depositing the electrically conductive material. In other embodiments, electrolytic plating operations may be used to deposit the electrically conductive material to the entire panel, and chemical, mechanical polishing (CMP) or Cu etching operations may be used after depositing the electrically conductive material. Various aforementioned operations or other compatible processes may be illustrated further during fabrication described in connection with FIGS. 5-8 according to various embodiments.

Various operations are described as multiple discrete operations in turn, in a manner that is most helpful in understanding the claimed subject matter. However, the order of description should not be construed as to imply that these operations are necessarily order dependent. Operations of the process 400 may be performed in another suitable order than depicted. In some embodiments, the process 400 may include actions described in connection with FIGS. 5-8 and vice versa.

FIG. 5 schematically illustrate cross-sectional views of some selected operations, prior to embedding a bridge, in connection with the package substrate fabrication process 400 illustrated in FIG. 4, in accordance with some embodiments. Referring to operation 592, the substrate is depicted subsequent to forming dielectric layer 510 over bridge 540, thus substantially embedding bridge 540 into the substrate, as can be seen.

In embodiments, dielectric layer 510 may be composed of any of a wide variety of suitable dielectric materials including, for example, epoxy-based laminate material, silicon oxide (e.g., SiO₂), silicon carbide (SiC), silicon carbonitride (SiCN), or silicon nitride (e.g., SiN, Si₃N₄, etc.). Other suitable dielectric materials may also be used including, for example, low-k dielectric materials having a dielectric constant k that is smaller than a dielectric constant k of silicon dioxide. In embodiments, dielectric layer 510 may include a polymer (e.g., epoxy-based resin) and may further include a filler (e.g., silica) to provide suitable mechanical properties that meet reliability requirements of the package. In embodiments, dielectric layer 510 may be formed as a film of polymer, such as by ABF lamination. In embodiments, dielectric layer 510 may have a suitable ablation rate to enable laser patterning as described herein.

In embodiments, dielectric layer 510 may be formed by depositing a dielectric material using any suitable technique including, for example, atomic layer deposition (ALD), physical vapor deposition (PVD) or chemical vapor deposition (CVD) techniques.

In embodiments, a bridge cavity may be provided for placement of bridge 540. In embodiments, at least a part of dielectric layer 510 may be removed by exposure to light and/or chemicals to form the bridge cavity. In embodiments, the bridge cavity may be laser drilled into dielectric layer 510. In embodiments, the bridge cavity may be left open during fabrication of the build-up layers of the substrate. In embodiments, the bridge cavity may be formed through the build-up layers using a patterning process. For example, dielectric layer 510 may be composed of a photosensitive material that is amenable to masking, patterning and etching, or develop processes.

In embodiments, bridge 540 may include a bridge substrate composed of glass or a semiconductor material, such as silicon (Si) having electrical routing interconnect features formed thereon, to provide a chip-to-chip connection between dies. In embodiments, bridge 540 may be mounted on the cavity of the substrate using an adhesive material or layer. The material of adhesive layer may include any suitable adhesive configured to withstand processes associated with fabrication of the substrate. In embodiments, chemical treatments, such as copper roughing technique, may be applied to improve adhesion between bridge 540 and its surrounding surfaces. In embodiments, bridge 540 may have routing features, such as pads 544, substantially inset into bridge 540 or protruding above the surface of the bridge substrate, and configured to route electrical signals to and from bridge 540.

In embodiments, the substrate may include multiple patterned metal layers, such as layers 518 and 526, configured to route electrical signals within or through the substrate. These patterned metal layers 518 and 526 may be separated by a dielectric layer 522. In embodiments, the patterned metal layers, e.g., layers 518 and 526, and any number of layers between or below these layers may be part of the substrate, and may be formed in any manner known in the art. For example, the patterned metal layer may be an inner or outermost conductive layer of a build-up layer formed with a semi-additive process (SAP). In embodiments, the substrate may also include multiple additional routing features, such as pads 514 or 530, configured to advance the electrical pathways within or through the substrate.

Referring to operation 594, the substrate is depicted subsequent to forming holes 550 on dielectric layer 510, as can be seen. In embodiments, a hole may be a microvia which may be laser drilled into dielectric layer 510 until a portion of the underlying routing features, such as pads 544, are exposed. In connection with the process 400, vias over bridge 540 may be drilled by applying laser projection patterning (LPP), which may utilize a homogenized laser beam such excimer laser with flat-top beam shape to create a projected mask pattern on to the surface of the dielectric layer 510 laminated over the embedded bridge 540.

In embodiments, the projection mask may be made from particular glass that has similar coefficient of thermal expansion (CTE) as bridge 540, which may be a silicon bridge (SiB) embedded in organic substrate. Similar CTE may improve Via-to-SiB pad alignment. Consequently, tighter via pitch may be achieved as compared to conventional CO₂ or solid state UV laser drilling approaches because of improved Via-to-SiB pad alignment and free of Galvo scanning error in this LPP approach. In embodiments, the throughput of via formation with this LPP approach may be improved as a result of the high microvia density at each of the SiB dies, e.g., density greater than 3000 microvias per each die.

Referring to operation 596, the substrate is depicted subsequent to forming holes 560 on dielectric layer 510 using a technique, such as employing CO₂ laser, to form holes. In embodiments, CO₂ or UV laser drilling (e.g., using Galvo scanning techniques), excimer laser projection patterning, or any other suitable technique may be used for via drilling in a region of the dielectric material that is not over the bridge 540. In embodiments, a desmear process may be subsequently applied to remove smeared dielectric material, such as epoxy-resin, from the bottom surface of cavities, e.g., cavities 550 and 560, to prevent the smear residue from forming a dielectric barrier.

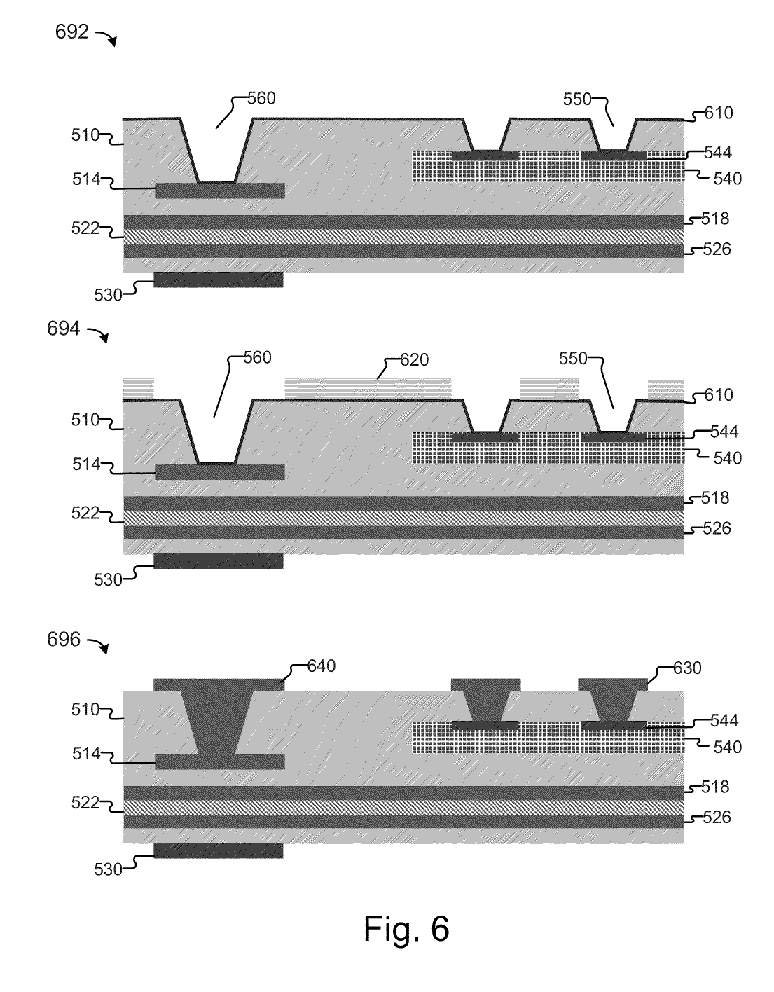

FIG. 6 schematically illustrates cross-sectional views of some other selected operations, in continuation to FIG. 5, in connection with the package substrate fabrication process illustrated in FIG. 4, in accordance with some embodiments. Referring to operation 692, metallic seed layer 610 may be deposited on the top of the substrate with any suitable techniques in various embodiments. In some embodiments, electroless plating may be used to form metallic seed layer 610. For example, a catalyst, such as palladium (Pd) may be deposited followed by an electroless copper (Cu) plating process. In some embodiments, a physical vapor deposition (i.e., sputtering) technique may be used to deposit metallic seed layer 610.

Referring to operation 694, the substrate is depicted subsequent to forming a photosensitive layer such as, for example, a dry film resist (DFR) layer 620, as can be seen. In embodiments, DFR layer 620 may be laminated and patterned using any technique known in the art. In embodiments, openings in DFR layer 620 may have bigger lateral dimensions than their underlying holes, as can be seen.

Referring to operation 696, the substrate is depicted subsequent to depositing a conductive material into cavities formed in dielectric layer 510 and openings formed by DFR layer 620, as can be seen. In embodiments, the conductive material may include the electrically conductive material, as discussed above in connection with process 400, such as metals including, e.g., nickel (Ni), palladium (Pd), gold (Au), silver (Ag), copper (Cu), aluminum (Al), and combinations thereof. In embodiments, holes 550 and 560 may be filled to form interconnection structures 630 and 640 respectively, for example, with an electrolytic plating process, such as an electrolytic copper plating process.

At operation 696, the DFR layer may be removed using any conventional strip process in embodiments. DFR stripping may further delineate interconnection structures 630 and 640 and expose the underlying dielectric layer 510. In embodiments, over-plated fill metal may be removed by one or more techniques, such as etching, buff grinding, chemical-mechanical polishing, etc. For example, chemical, mechanical polishing (CMP) or buff grinding may be used to first planarize interconnection structures 630 and 640, and then etching may be employed to remove any remaining electroless plated metal.

In embodiments, interconnection structures 630 may protrude above the surface of the substrate, and be configured to connect bridge 540 with dies above the substrate. In embodiments, other layered FLI interconnect structures may also be formed in part by the operations of 692, 694, and 696.

FIG. 7 schematically illustrates cross-sectional views of yet some other selected operations in connection with the package substrate fabrication process illustrated in FIG. 4, in accordance with some embodiments. Referring to operation 792, the substrate is depicted subsequent to forming dielectric layer 710 over bridge 740, thus substantially embedding bridge 740 into the substrate, as can be seen.

In embodiments, dielectric layer 710, similar to dielectric layer 510 in FIG. 5, may be composed of any of a wide variety of suitable dielectric materials, formed using any suitable technique, and may have a suitable ablation rate to enable laser patterning as described herein.

In embodiments, bridge 740 may include a bridge substrate composed of glass or a semiconductor material, such as silicon (Si) having electrical routing interconnect features formed thereon, to provide a chip-to-chip connection between dies. In embodiments, bridge 740 may have routing features, such as pads 744, substantially inset into bridge 740 or protruding above the surface of the bridge substrate, and configured to route electrical signals to and from bridge 740.

In embodiments, the substrate may include multiple patterned metal layers, such as layer 718 and 726, configured to route electrical signals within or through the substrate. These patterned metal layers 718 and 726 may be separated by a dielectric layer 722. In embodiments, the patterned metal layers, e.g., layers 718 and 726, and any number of layers between or below these layers may be part of the substrate, and may be formed in any manner known in the art. For example, the patterned metal layer may be an inner or outermost conductive layer of a build-up layer formed with a semi-additive process (SAP). In embodiments, the substrate may also include multiple additional routing features, such as pads 714 or 730, configured to advance the electrical pathways within or through the substrate.

Referring to operation 794, the substrate is depicted subsequent to forming various cavities on dielectric layer 710, as can be seen. In connection with the process 400, vias, pads, traces, or other routing features may be drilled by applying LPP, which may utilize a homogenized laser beam such excimer laser with flat-top beam shape to create a projected mask pattern on to the surface of the dielectric layer 710. In embodiments, cavity 770 may be a structure of a pad and a via hole over bridge 740, which may be laser drilled into dielectric layer 710 until a portion of the underlying routing features, such as pads 744, are exposed. The cavity 770 having the profile of the pad and the via may be simultaneously formed during a single exposure operation in some embodiments. In embodiments, cavity 760 may be a structure of a pad and a via hole over pad 714, which may be laser drilled in a region of the dielectric material that is not over bridge 740. The cavity 760 and the cavity 770 may be simultaneously formed during a same exposure operation in some embodiments. In embodiments, cavity 750 may be a trace structure, which may be laser drilled on the top of dielectric layer 710. Two or more of the cavities 750, 760 and 740 may be simultaneously formed during a same exposure operation in some embodiments. In embodiments, a grey scale mask may be used to realize different etching depth for via, pad, trace, and/or other routing features, thus other routing features may also be formed on dielectric layer 710 using LPP technology, concurrently with aforementioned various cavities. In embodiments, a desmear process may be subsequently applied to remove smeared dielectric material, such as epoxy-resin, from the bottom surface of cavities, e.g., cavities 750, 760, and 770.

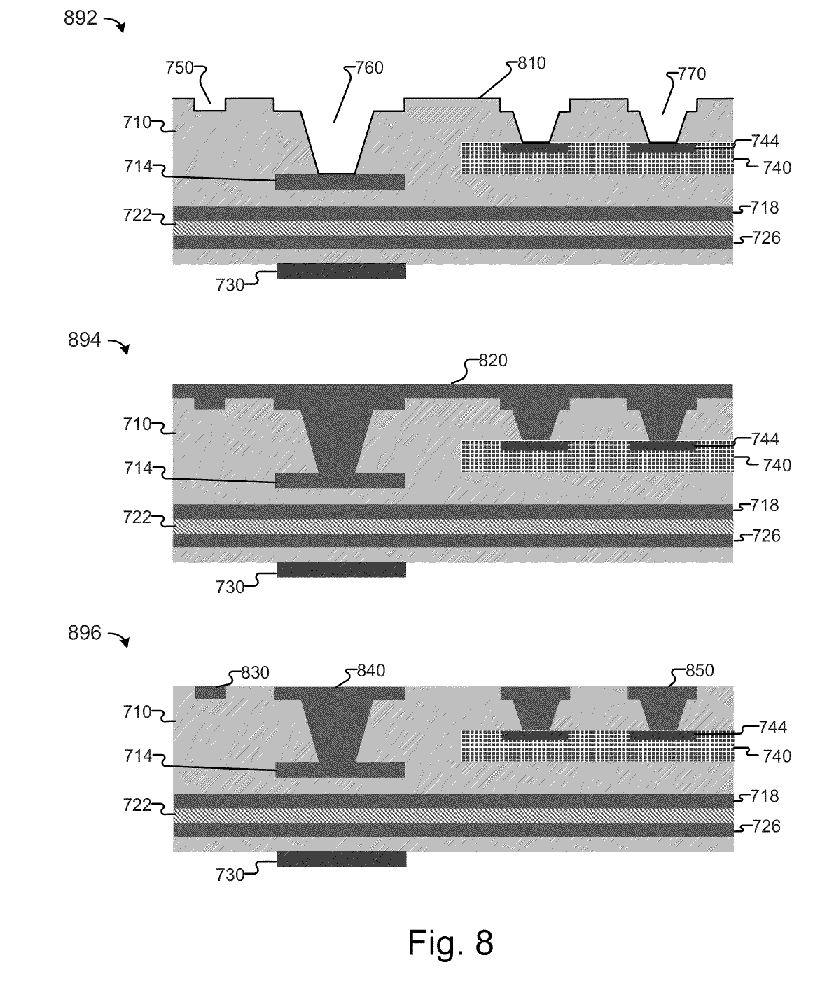

FIG. 8 schematically illustrates cross-sectional views of some other selected operations, in continuation to FIG. 7, in connection with the package substrate fabrication process illustrated in FIG. 4, in accordance with some embodiments. Referring to operation 892, metallic seed layer 810 may be deposited on the top of the substrate with any suitable techniques in various embodiments. In some embodiments, electroless plating may be used to form metallic seed layer 810. For example, a catalyst, such as palladium (Pd) may be deposited followed by an electroless copper (Cu) plating process. In some embodiments, a physical vapor deposition (i.e., sputtering) technique may be used to deposit metallic seed layer 810.

Referring to operation 894, the substrate is depicted subsequent to depositing a conductive material into cavities formed in dielectric layer 710, as can be seen. In embodiments, the conductive material may include the electrically conductive material, as discussed above in connection with process 400, such as metals including, e.g., nickel (Ni), palladium (Pd), gold (Au), silver (Ag), copper (Cu), and combinations thereof. In embodiments, cavities 750, 760, and 770 may be filled, for example, with an electrolytic plating process, such as an electrolytic copper plating process, and resulting in an over-plated layer 820.

Referring to operation 896, the substrate is depicted subsequent to removing the over-plated layer 820 on dielectric layer 710, as can be seen. In embodiments, over-plated layer 820 may be removed by one or more techniques, such as etching, buff grinding, chemical-mechanical polishing, etc. In embodiments, discrete interconnection structures 830, 840, and 850 may be formed after operation 896, and be configured to connect various internal routing features of the substrate, such as bridge 540, with electrical components above the substrate, such as other dies.

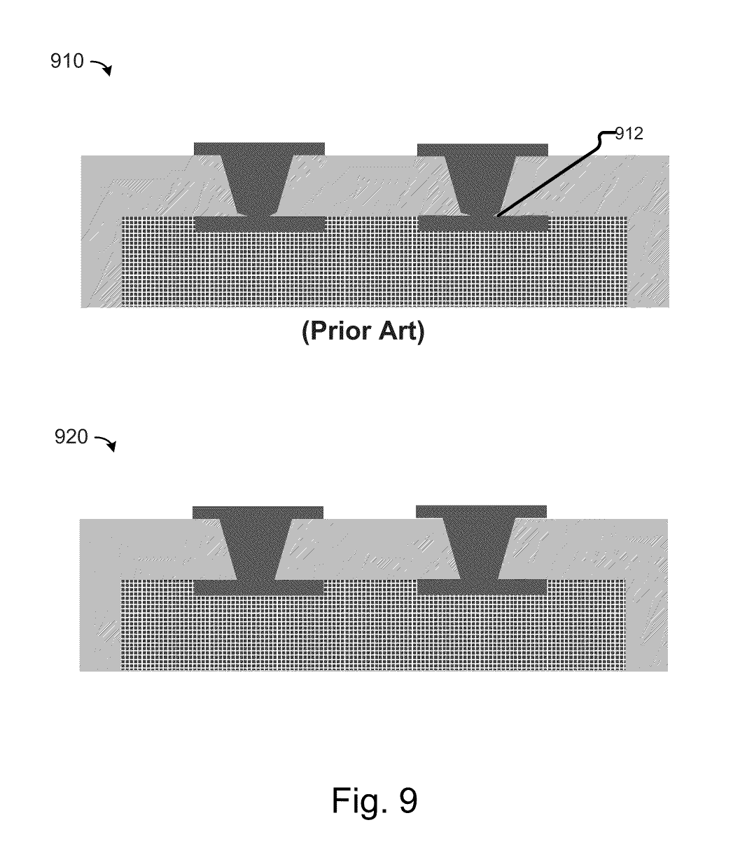

FIG. 9 schematically illustrates cross-sectional views of some selected vias made using projection patterning, in accordance with some embodiments. Image 920 shows a via which may be produced through the illustrative processes described in reference to FIGS. 4-8 above. In embodiments, vias or other routing features formed by the LPP in light of the present disclosure may have some distinguishing features compared with vias formed by non-LPP techniques.

As shown in image 910, via footing 912 (i.e., protrusion of dielectric material such as resin at the bottom of the via) may be observed in a typical via shape formed by a non-LPP solid state UV laser because beam shaping technology in a non-LPP setting may be generally unable to shape a perfect top-hat beam profile on the substrate surface. However, with the LPP approach as disclosed above, the via footing may be eliminated. In embodiments, the homogenized excimer laser may be projected on the substrate surface through a mask. A tapered profile from a top of the via to a bottom of the via and a substantially flat bottom profile of the via may be formed thereinafter, as can be seen in image 920. The angle of the tapered profile from the top to the bottom may be substantially constant, and via footing may be eliminated. In embodiments, the whole bottom of the via may be configured to be in direct electrical contact with an electrically conductive feature of the die, such as illustrated at FIGS. 5-8. In embodiments, these unique feature qualities may be embodied in features such as damascene structures (not shown) including, for example, pad and/or trace, as shown schematically as embedded pad and/or trace features in FIGS. 7 and 8.

In embodiments, the alignment of the microvia projected from the mask to the pad on a SiB die may be improved with the LPP approached illustrated herein. As an example, the CTE of the glass mask may range between about 3-8.5 ppm/° C. depending on the glass material to be chosen. Glass material may be selected to match the effective CTE of the die. For die with Cu features, the effective CTE may vary depending on the Cu design. With similar or matching CTE, the deformation of the mask and the silicon die are similar under the similar temperature environment. Thus, the alignment of the microvia projection may be improved.

Embodiments of the present disclosure may be implemented into a system using any suitable hardware and/or software to configure as desired. FIG. 10 schematically illustrates a computing device that includes a projected mask pattern on a substrate made using LPP, as described herein, in accordance with some embodiments. The computing device 1000 may house a board such as motherboard 1002. Motherboard 1002 may include a number of components, including but not limited to processor 1004 and at least one communication chip 1006. Processor 1004 may be physically and electrically coupled to motherboard 1002. In some implementations, the at least one communication chip 1006 may also be physically and electrically coupled to motherboard 1002. In further implementations, communication chip 1006 may be part of processor 1004.

Depending on its applications, computing device 1000 may include other components that may or may not be physically and electrically coupled to motherboard 1002. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

Communication chip 1006 may enable wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 1006 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. Communication chip 1006 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1006 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1006 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. Communication chip 1006 may operate in accordance with other wireless protocols in other embodiments.

Computing device 1000 may include a plurality of communication chips 1006. For instance, a first communication chip 1006 may be dedicated to shorter range wireless communications such as Wi-Fi and Bluetooth, and a second communication chip 1006 may be dedicated to longer range wireless communications such as GPS, EDGE, GPRS, CDMA, WiMAX, LTE, Ev-DO, and others.

Processor 1004 of computing device 1000 may be packaged in an IC assembly (e.g., IC assembly 100 of FIG. 1) that includes a substrate (e.g., package substrate 150 of FIG. 1) having an embedded bridge with interconnect structures formed according to techniques as described herein. For example, circuit board 190 of FIG. 1 may be motherboard 1002, and processor 1004 may be die 110 coupled to package substrate 150 using interconnect structure 130 of FIG. 1. Package substrate 150 and motherboard 1002 may be coupled together using package level interconnects. The term “processor” may refer to any device or portion of a device that processes electronic data from registers and/or memory to transform that electronic data into other electronic data that may be stored in registers and/or memory.

Communication chip 1006 may also include a die (e.g., die 120 of FIG. 1) that may be packaged in an IC assembly (e.g., IC assembly 100 of FIG. 1) that includes a substrate (e.g., package substrate 150 of FIG. 1) having an embedded bridge with interconnect structures formed according to techniques as described herein. In further implementations, another component (e.g., memory device or other integrated circuit device) housed within computing device 1000 may include a die (e.g., die 110 of FIG. 1) that may be packaged in an IC assembly (e.g., IC assembly 100 of FIG. 1) that includes a substrate (e.g., package substrate 150 of FIG. 1) having an embedded bridge with interconnect structures formed according to techniques as described herein. According to some embodiments, multiple processor chips and/or memory chips may be disposed on a same package substrate and the embedded bridges with layered interconnect structures may electrically route signals between any two of the processor or memory chips. In some embodiments, a single processor chip may be coupled with another processor chip using a first embedded bridge and a memory chip using a second embedded bridge.

In various implementations, computing device 1000 may be a laptop, a netbook, a notebook, an Ultrabook™, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

### Examples

Example 1 is a method for forming one or more vias which may include projecting a laser beam through a mask with a preconfigured pattern to drill a projected mask pattern through a dielectric material of a substrate in accordance with the preconfigured pattern, wherein the projected mask pattern includes a via disposed over a die that is embedded in the dielectric material.

Example 2 may include the subject matter of Example 1, and may further include modifying the laser beam such that during projecting the laser beam, the laser beam covers only a portion of the mask, wherein the portion of the mask may correspond to an area of the dielectric material over the die.

Example 3 may include the subject matter of Example 1 or 2, and may further include moving the mask and the substrate with a coordinated opposing motion at a constant or variable speed during projecting the laser beam.

Example 4 may include the subject matter of any one of Examples 1-3, and further specifies that projecting the laser beam removes a majority of the dielectric material in the via. Example 4 may further include performing a desmear process to remove any residual dielectric material in the via.

Example 5 may include the subject matter of any one of Examples 1-4, and further specifies that the laser beam may include an excimer laser beam, and the via is a first via. Example 5 may further include forming a second via on the surface of the dielectric material by a carbon dioxide laser or solid state UV laser wherein the second via is disposed in a region of the dielectric material that is not over the die.

Example 6 may include the subject matter of any one of Examples 1-5, and may further include depositing a conductive material into the via using a semi-additive process; and removing at least a portion of the conductive material with an electroless removal process.

Example 7 may include the subject matter of any one of Examples 1-6, and may further include depositing a conductive material into the via using an electrolytic plating process; and removing at least a portion of the conductive material with a chemical-mechanical polishing process or an etching process.

Example 8 may include the subject matter of any one of Examples 1-7, and further specifies that the projected mask pattern may include at least one routing feature of vias, pads, or traces disposed in a region of the dielectric material that is not over the die, and the at least one routing feature may be concurrently formed with the via disposed over the die.

Example 9 may include the subject matter of any one of Examples 1-8, and further specifies that the dielectric material may include epoxy; the die may include silicon, and the mask may include a glass material having a similar coefficient of thermal expansion as the die.

Example 10 may include the subject matter of any one of Examples 1-9, and further specifies that the mask may be a greyscale mask configured to create cavities with different depth in the dielectric material.

Example 11 may include the subject matter of any one of Examples 1-10, and further specifies that the laser beam may be a homogenized flat-top laser beam.

Example 12 may include the subject matter of any one of Examples 1-11, and further specifies that the die may be a first die including a bridge interconnect configured to route electrical signals between a second die and a third die through the substrate, and wherein the via may be configured to route the electrical signals.

Example 13 may include the subject matter of any one of Examples 1-12, and further specifies that the via may be one of a plurality of vias having a pitch of 55 micrometers or less between individual vias of the plurality of vias.

Example 14 may include the subject matter of any one of Examples 1-13, and may further include providing the die embedded in the dielectric material of the substrate.

Example 15 is a storage medium having stored therein instructions configured to cause a device, in response to execution of the instructions by the device, to practice the subject matter of any one of Examples 1-14. The storage medium may be non-transient.

Example 16 is an apparatus for contextual display which may include means to practice the subject matter of any one of Examples 1-14.

Example 17 is a product which may be fabricated by any method disclosed by any one of Examples 1-14.

Example 18 is an apparatus which may include a substrate; a bridge embedded in the substrate and configured to route electrical signals between a first die and a second die; and a plurality of vias connected to the bridge and configured to route the electrical signals through at least a portion of the substrate, wherein individual vias of the plurality of vias have a tapered profile from a top of the individual vias to a bottom of the individual vias, an angle of the tapered profile from the top to the bottom is substantially constant, and the whole bottom of the individual vias is in direct electrical contact with an electrically conductive feature of the die.

Example 19 may include the subject matter of Example 18, and further specifies that the bottom of each of the plurality of vias is substantially flat.

Example 20 may include the subject matter of Example 18 or 19, and further specifies that individual vias of the plurality of vias have no via footing.

Example 21 may include the subject matter of any one of Examples 18-20, and further specifies that the plurality of vias may have a pitch of 55 micrometers or less between individual vias of the plurality of vias.

Example 22 may include the subject matter of any one of Examples 18-21, and further specifies that the first die may include a processor and the second die may include a memory die or another processor.

Example 23 may include the subject matter of any one of Examples 18-22, and further specifies that the bridge may include a semiconductor material including silicon, and wherein the substrate may include an epoxy-based dielectric material.

Example 24 is an system which may include a first die and a second die; and a substrate with an embedded bridge and a plurality of vias disposed between the embedded bridge and at least one of the first die and the second die; wherein the plurality of vias may be connected to the embedded bridge and configured to route electrical signals through at least a portion of the substrate, and individual vias of the plurality of vias have a tapered profile from a top of the individual vias to a bottom of the individual vias, an angle of the tapered profile from the top to the bottom is substantially constant and the whole bottom of the individual vias is in direct electrical contact with an electrically conductive feature of the die.

Example 25 may include the subject matter of Example 24, and may further include a circuit board, wherein the substrate may be electrically coupled with the circuit board, and the circuit board may be configured to route the electrical signals of the first die or the second die; and one or more of an antenna, a display, a touchscreen display, a touchscreen controller, a battery, an audio codec, a video codec, a power amplifier, a global positioning system device, a compass, a Geiger counter, an accelerometer, a gyroscope, a speaker, or a camera coupled with the circuit board.

Example 26 may include the subject matter of Example 24 or 25, and further specifies that the system may be one of a wearable computer, a smartphone, a tablet, a personal digital assistant, a mobile phone, an ultra mobile PC, an ultrabook, a netbook, a notebook, a laptop, a desktop computer, a server, a printer, a scanner, a monitor, a set-top box, an entertainment control unit, a digital camera, a portable music player, or a digital video recorder.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A method, comprising:
projecting a laser beam through a mask with a preconfigured pattern to drill a projected mask pattern through a dielectric material of a substrate in accordance with the preconfigured pattern, wherein the projected mask pattern includes a via disposed over a die that is embedded in the dielectric material.

2. The method of claim 1, further comprising:
providing the die embedded in the dielectric material of the substrate.

3. The method of claim 1, further comprising:
modifying the laser beam such that during projecting the laser beam, the laser beam covers only a portion of the mask, wherein the portion of the mask corresponds to an area of the dielectric material over the die.

4. The method of claim 1, further comprising:
moving the mask and the substrate with a coordinated opposing motion at a constant or variable speed during projecting the laser beam.

5. The method of claim 1, wherein projecting the laser beam removes a majority of the dielectric material in the via, the method further comprising performing a desmear process to remove any residual dielectric material in the via.

6. The method of claim 1, wherein the laser beam comprises an excimer laser beam and the via is a first via, the method further comprising:
forming a second via on the surface of the dielectric material by a carbon dioxide laser or solid state UV laser wherein the second via is disposed in a region of the dielectric material that is not over the die.

7. The method of claim 1, further comprising:
depositing a conductive material into the via using a semi-additive process; and
removing at least a portion of the conductive material with an electroless removal process.

8. The method of claim 1, further comprising:
depositing a conductive material into the via using an electrolytic plating process; and
removing at least a portion of the conductive material with a chemical-mechanical polishing process or an etching process.

9. The method of claim 1, wherein the projected mask pattern include at least one routing feature of vias, pads, or traces disposed in a region of the dielectric material that is not over the die, and the at least one routing feature is concurrently formed with the via disposed over the die.

10. The method of claim 1, wherein the dielectric material comprises epoxy, the die comprises silicon, and the mask comprises a glass material having a similar coefficient of thermal expansion as the die.

11. The method of claim 1, wherein the mask is a greyscale mask configured to create cavities with different depth in the dielectric material.

12. The method of claim 1, wherein the laser beam is a homogenized flat-top laser beam.

13. The method of claim 1, wherein the die is a first die including a bridge interconnect configured to route electrical signals between a second die and a third die through the substrate, and wherein the via is configured to route the electrical signals.

14. The method of claim 1, wherein the via is one of a plurality of vias having a pitch of 55 micrometers or less between individual vias of the plurality of vias.

15. At least one non-transient storage medium, comprising:
a plurality of instructions configured to cause a device, in response to execution of the instructions by the device, to perform the method 1.

16. A product fabricated by the method of claim 1.

17. An apparatus, comprising:
a substrate;
a bridge embedded in the substrate and configured to route electrical signals between a first die and a second die; and
a plurality of vias connected to the bridge and configured to route the electrical signals through at least a portion of the substrate, wherein individual vias of the plurality of vias have a tapered profile from a top of the individual vias to a bottom of the individual vias, an angle of the tapered profile from the top to the bottom is substantially constant, and the whole bottom of the individual vias is in direct electrical contact with an electrically conductive feature of the die.

18. The apparatus of claim 17, wherein the bottom of each of the plurality of vias is substantially flat.

19. The apparatus of claim 17, wherein individual vias of the plurality of vias have no via footing.

20. The apparatus of claim 17, wherein the first die includes a processor and the second die includes a memory die or another processor.

21. The apparatus of claim 17, wherein the bridge comprises a semiconductor material including silicon, and wherein the substrate comprises an epoxy-based dielectric material.

22. The apparatus of claim 17, wherein the plurality of vias have a pitch of 55 micrometers or less between individual vias of the plurality of vias.

23. The apparatus of claim 17, further comprising:
the first die and the second die;
a circuit board, wherein the substrate is electrically coupled with the circuit board and the circuit board is configured to route the electrical signals of the first die or the second die; and
one or more of an antenna, a display, a touchscreen display, a touchscreen controller, a battery, an audio codec, a video codec, a power amplifier, a global positioning system device, a compass, a Geiger counter, an accelerometer, a gyroscope, a speaker, or a camera coupled with the circuit board.
